(19) United States
(12) Patent Application Publication
(10) Pub. No.: US 2024/0210475 A1
(43) Pub. Date: Jun. 27, 2024

(54) DETECTION OF WELDED CONTACTORS

(71) Applicant: Northvolt Systems AB, Stockholm (SE)

(72) Inventors: August HULTMAN, Bromma (SE); Anders MARKLAND, Järfälla (SE)

(21) Appl. No.: 18/392,096

(22) Filed: Dec. 21, 2023

(30) Foreign Application Priority Data
Dec. 22, 2022 (SE) 2251561-3

(51) Int. Cl. G01R 31/364; G01R 31/367

(52) U.S. Cl. CPC G01R 31/364; G01R 31/367

(57) ABSTRACT

A method of indicating that a conducting member has not fully disengaged from two electrical contacts. The conducting member is movably mounted on an actuator, the actuator being adapted to move between a deactivated position and an activated position, wherein in the activated position the conducting member is in contact with both the electrical contacts. The method comprises: sending an activation signal to move the actuator to the activated position; detecting that the actuator has caused an electrical circuit to be closed; and if the time interval between the sending step and the detecting step is less than a threshold, generating an output indicating that the conducting member was not fully disengaged before the activation signal was sent.

### FIELD OF THE INVENTION

The invention relates to detection of welded contacts and especially, welding of a conducting member to electrical contacts on a contactor, such as that used for electrically coupling a battery pack to a load.

### BACKGROUND TO THE INVENTION

Contactors are used to connect a power pack, such as a battery pack, to an electrical load. Typically, a contactor comprises two high-voltage terminals that can be interconnected by an electrically actuated metal contact, usually in the form of a metal bar, to complete the electrical circuit and electrically couple the power pack to the electrical load. When operating correctly, the metal contact comes into contact with both terminals and also disconnects from both terminals.

For example, such systems are used in electric vehicles to electrically couple the vehicle battery pack to the vehicles electrical systems, including the electrical motors.

However, one or both sides of the metal contact may become welded to the high-voltage terminals, for instance as a result of arcing. Current methods of weld detection typically rely on detection or measuring of output from a feedback contact that is mechanically coupled to the main, metal contact but is electrically isolated from the metal contact. However, this approach may fail to detect partially welded contactors when the contactor design has too small a margin for the feedback. That is, ideally when the main, metal contact opens, the feedback contact only opens when the metal contact has moved a sufficiently large enough distance to be certain that the metal contact is fully open. However, many contactors are poorly designed for safety, with the design margins too small to reliably indicate that the main, metal contact has not fully opened. Some contactor designs can even output false negative (open) output on the normally open feedback relay output when the contactor has been welded or partially welded. The design of some contactors is such that a control signal sent to the contactor to cause the contactor to disengage from the main power pack terminals has the effect of causing the feedback contact to disengage even though the main, metal contact remains engaged with the terminals due to either a partial weld or a full weld of the metal contact to the terminals.

When the contact is partially welded, i.e., when one side of the contact is welded to one of the terminals, the insulative distance between the metal contact and the terminals can be greatly reduced even when the metal contact is partially disconnected.

This can in turn lead to arcing, rendering the contactor unsafe. A partial weld cannot currently be detected, even on modern contactor designs. A full weld is when the metal contact is welded to both terminals of the power pack.

In such partial welding or full welding of the main contact, the disengagement of the feedback contact therefore, incorrectly indicates disengagement of the main electrical contact from the terminals when in fact there has not been a full disengagement of the main electrical contact.

For example, partial disengagement may lead to dangerous arcing and therefore detecting partial disengagement enhances the safety of the system.

### SUMMARY OF INVENTION

According to a first aspect of the invention, there is provided a method of indicating that a conducting member has not fully disengaged from two electrical contacts, the conducting member movably mounted on an actuator, the actuator being adapted to move between a deactivated position and an activated position, wherein in the activated position the conducting member is in contact with both the electrical contacts, the method comprising:
sending an activation signal to move the actuator to the activated position;
detecting that the actuator has caused an electrical circuit to be closed; and
if the time interval between the sending step and the detecting step is less than a threshold, generating an output indicating that the conducting member was not fully disengaged before the activation signal was sent.

Advantageously, by detecting a partial or full weld, the method increases the safety of the circuit containing the conducting member and the two electrical contacts. The invention thus provides a method of detecting a faulty contactor when other methods, such as use of a feedback contact, may fail or provide a false negative.

According to a second aspect of the invention, there is provided apparatus for implementing a method according to the first aspect, the apparatus comprising:
a processor; and
an output device;
   wherein the processor causes the activation signal to be sent to the actuator to move the actuator to the activated position; the processor detects that the actuator has caused an electrical circuit to be closed; and
if the time interval between the sending step and the detecting step is less than a threshold, generating an output;
and sending the output to the output device to cause the output device to indicate that the conducting member was not fully disengaged before the activation signal was sent.

Preferably, the generating comprises generating an output indicating that the conducting member was only partially disengaged before the activation signal was sent. Advantageously, by detecting a partial weld the method enhances the safety of the circuit.

Alternatively, the generating comprises generating an output indicating that the conducting member was fully engaged before the activation signal was sent. Advantageously, by detecting a full weld the method enhances the safety of the circuit.

Preferably, the electrical circuit that is closed comprises a feedback contact. Advantageously, the time interval for the feedback contact to close is proportional to the time interval for the metal contact to come into contact with the terminals.

Alternatively, the electrical circuit that is closed comprises the conducting member and the two electrical contacts. Advantageously, eliminating the feedback circuit provides a system with fewer components and therefore easier to manufacture.

Preferably, the threshold is based on a reference time interval between a sending of an activation signal to a reference actuator and detecting that the reference actuator has caused a reference circuit to be closed. Preferably, the reference circuit comprises: a reference feedback contact, where the electrical circuit that is closed comprises a feedback contact; or a reference conducting member and two reference electrical contacts, where the electrical circuit that is closed comprises the conducting member and the two electrical contacts. Advantageously, basing the threshold on reference time intervals determined from a reference circuit improves the accuracy of detecting a failure of the metal contact to fully disengage.

Preferably, the conducting member, the two electrical contacts and the actuator are parts of an electrical contactor.

Preferably, the method further comprises adjusting the time interval by applying a coefficient based on at least one physical characteristic. Advantageously, adjusting the time interval improves the accuracy of the detection by correcting for environmental factors and/or for individual characteristics of the components in the system.

Typically, the at least one physical characteristic comprises one or more of temperature, current, wear, tolerances, and voltage. Preferably, the at least one physical characteristic is one or more of a temperature of a coil comprised in the actuator or an ambient temperature of surroundings of a coil comprised in the actuator, average electrical current through the conducting member, integral of electrical current through the conducting member, and voltage across the actuator. The average may be a weighted average. Alternatively, or in addition, the at least one physical characteristic comprises a temperature of the contactor or an ambient temperature of surroundings of the contactor.

Typically, the apparatus may further comprise at least one sensor or detector to sense or detect the at least one physical characteristic.

The actuator may comprise a solenoid.

The contactor may be located within a housing. Where the time interval is adjusted by applying a coefficient based on at least one physical characteristic and the at least one physical characteristic comprises at least temperature, a temperature sensor may also be located within the housing.

### BRIEF DESCRIPTION OF THE DRAWINGS

Examples of the present invention will now be described in detail with reference to the accompanying drawings, in which:

FIG. 1 is a schematic drawing of a contactor that may be used with the present invention;

FIG. 2 illustrates schematically an electrical circuit for use with the contactor shown in FIG. 1;

FIGS. 3a-3c is a schematic drawing illustrating the operation of the contactor shown in FIG. 1; and

FIG. 4 shows a block diagram of a contactor control circuit, such as may be used with the contactor of FIG. 1.

### DETAILED DESCRIPTION

### Contactor

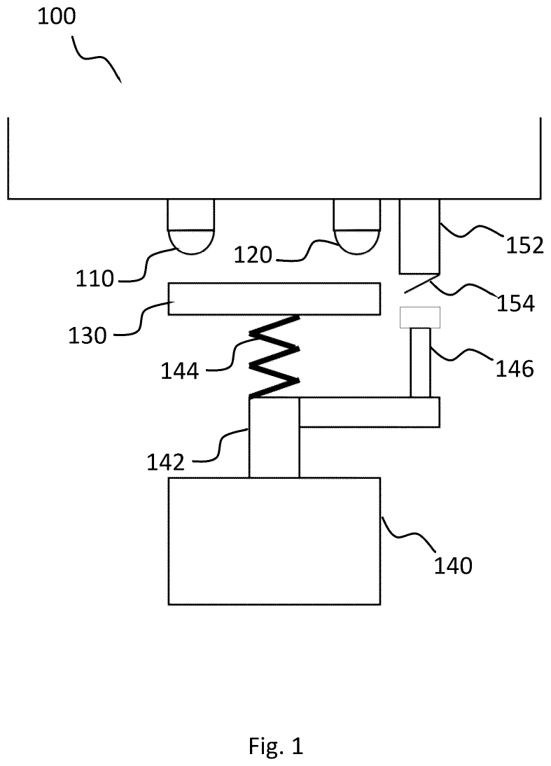

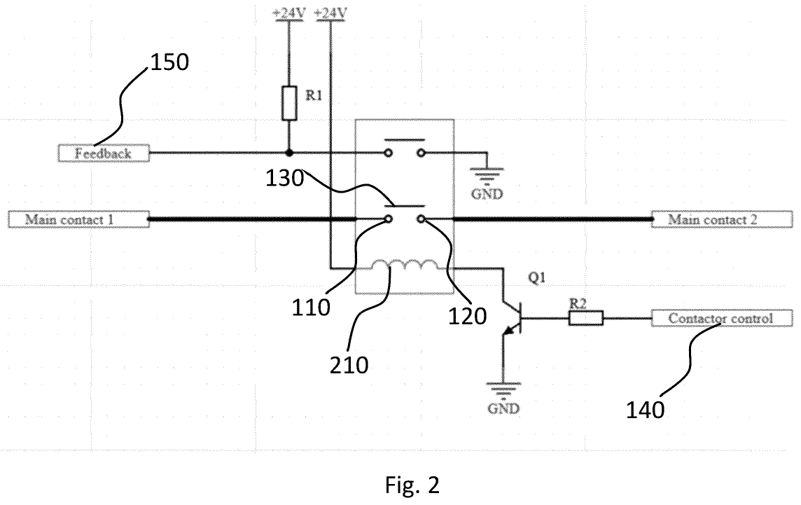

A typical contactor 100, such as shown in FIG. 1 with an appropriate control circuit shown in FIG. 2, comprises two terminals 110, 120 designed to be interconnected by an actuated metal contact 130. The terminals 110, 120 may be high-voltage terminals. The contactor 100 may further comprise a feedback circuit 150, at least one feedback terminal 152 and at least one a feedback switch 154.

The metal contact 130 may be actuated by an actuator 140, preferably an electrical actuator. The actuator comprises a plunger 142 and a spring 144. The actuator may further comprise at least one feedback plunger 146.

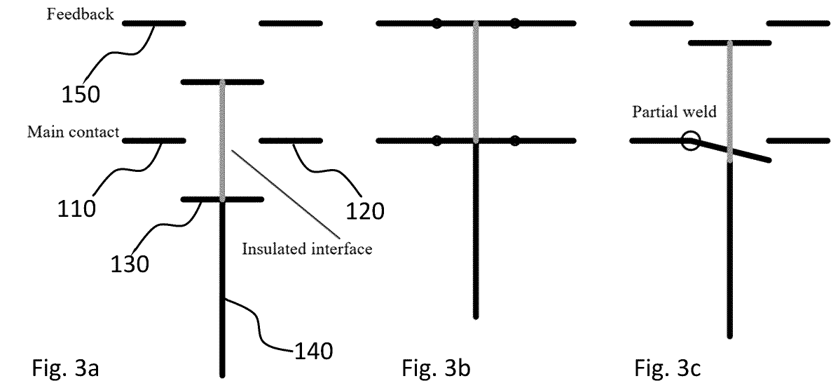

FIGS. 3a-3c show a schematic of contactor operation. As shown in FIG. 3a, to close the contacts the actuator 140 moves towards the terminals 110, 120 such that the metal contact 130 eventually engages the terminals 110, 120. If the feedback circuit 150 is present the actuator continues to move in the direction towards the terminals 110, 120, such that the spring 144 is compressed and the feedback plunger 146 engages the feedback switch 154 to close the feedback circuit 150. Alternatively, a pair of feedback terminals 152 may each be engaged by a secondary contact 148, 149 on a feedback plunger 146, 147 to close the feedback circuit 150 without the need for a switch. The secondary contacts 148, 149 are electrically insulated from the metal contact 130. Closing of the feedback circuit confirms that the two terminals 110, 120 of the contactor are engaged (FIG. 3b).

The spring loading ensures good contact of the metal contact 130 with the terminals 110, 120 and allows the metal contact 130 to “float” on the actuator 140.

The actuator 140 may comprise a solenoid 210 (see FIG. 2). The actuator 140 may comprise a core. The relative positions of the core and the solenoid 210 are moveable so as to move the plunger 142, the spring 144, and the feedback plunger 146, 147 with respect to the terminals 110, 120 and the feedback terminals 152. The core may be moveable, with a fixed coil or solenoid 210. Alternatively, the coil or solenoid 210 may be moveable, with a fixed core.

### Partial Welding of Contactor Contacts

Arcing can cause welding of one or both sides of the metal contact 130 to the terminals 110, 120. In a partial weld one side of the metal contact 130 is welded to one of the terminals 110 while the other side can still disengage from the other terminal 120. In a partial weld the actuator 140 can therefore be prevented from retracting entirely, compromising the insulative distance between the metal contact 130 and the terminals 110, 120.

When a partially welded contactor is opened one side of the metal contact is welded and causes the mechanism to get stuck close to the normal activation point, as shown schematically in FIG. 3c. The main circuit opens, i.e., one of the terminals 110, 120 is disengaged, but with less movement. When a partially welded contactor is closed next time, the time between supplying power to activate it to getting the feedback is greatly reduced due to shorter travel distance.

By measuring the timing between activation and feedback on every start-up, a partially welded contactor can be detected, and the system can be put in safe-state to not risk any further damage or injuries by electrocution. By measuring the time between the activation signal sent to the actuator and the engagement of the feedback connection, welding that prevents the actuator from retracting entirely can be detected.

Contactors typically operate in pairs. In such an instance relative timing may be used, i.e., the difference in activation time between two or more contactors being compared. In other situations, absolute timing may be used.

The time of activation of a contactor may be affected by one or more physical characteristics. For instance, voltage across the actuator 140, instant and weighted average voltage across the actuator 140, ambient temperature, temperature of a coil of the solenoid, the position in lifecycle of the contactor, wear on the components, manufacturing tolerances of the components, and/or the electrical current through the conducting member may affect the activation time of the contactor. The electrical current through the conducting member may be a weighted average over a period of time. Preferably, the more recent a measurement of the voltage is, the more weight is allocated in the weighted average.

The contactor may be placed in a housing 160. A temperature sensor 170 may also be placed in the housing 160 and used to measure the ambient temperature. The ambient temperature may then be used to determine a coefficient to adjust the measured time interval to determine the time of activation.

Similarly, electrical current such as average current through the conducting member 130 may be used to calculate the coefficient. The average may also be a weighted average. Preferably, the more recent a measurement of the current is, the more weight it is allocated in the weighted average.

The method may be implemented in software using readily available signals or may be implemented in hardware using dedicated components.

Detecting Timing with a Feedback Circuit

In a contactor with a feedback circuit such as the feedback circuit 150 the time interval between a signal sent to the actuator 140 to actuate the main circuit and the feedback circuit 150 being closed can be measured to detect a partial weld. This is because if one of the terminals 110 had disengaged but the other terminal 120 had not disengaged, the initial distance between the metal contact 130 and the disengaged terminal 120 would have been shorter than it would have been if both terminals 110, 120 had disengaged. As a consequence, once the actuator 140 initiates closing of the circuit the metal contact 130 will connect with the terminal 120 in a shorter time than it would have if the circuit had been completely opened. The shorter time interval to closure, indicated by the feedback circuit 150, indicates the presence of a partial weld.

Detecting Timing with Voltage Measurement

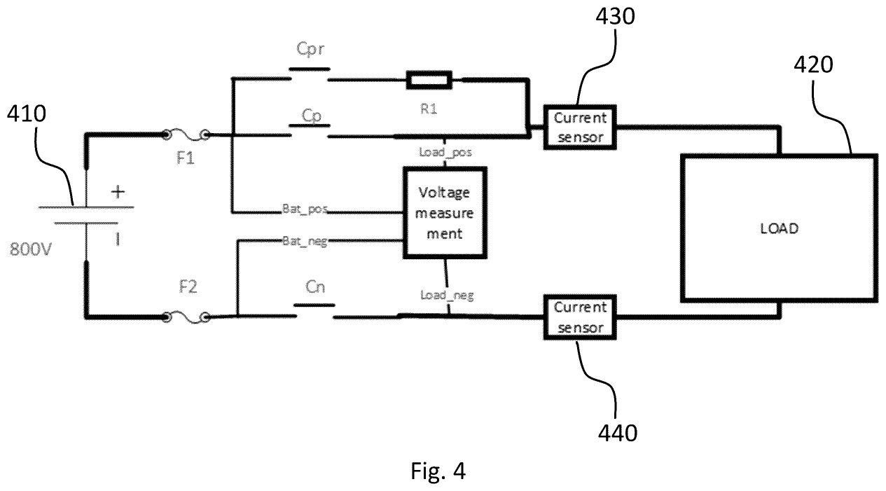

In a system without the feedback circuit 150 another trigger method for stopping counting time to circuit closure is needed. Without an auxiliary feedback switch integrated in the contactor a voltage or current measurement can be used for detection instead. FIG. 4 illustrates a circuit with a battery pack 410 and a load 420 that permits the invention to be used without a feedback mechanism. The circuit comprises at least one fuse F1, F2 and a plurality of contactors, for instance a positive contactor Cₚ, a negative contactor Cₙ, and a pre-charge contactor Cₚᵣ. The circuit further comprises a pre-charge resistor R1. The circuit also comprises at least one current sensor 430, 440, configured to detect the current to the load 420. The load 420 may comprise an inverter and an electric motor.

Detecting a partial weld without feedback using a voltage measurement requires a voltage balancing circuit (not shown in FIG. 4). A typical voltage balancing circuit comprises two resistors connected between positive and negative load connectors, with a battery negative connected in between the two resistors. With no other connection between the load and the battery, such a voltage balancing circuit will centre the voltage around the battery negative.

A current sensor of the at least one current sensor 430, 440 may be used to detect that negative and positive or pre-charge contactor has been closed. A second current sensor may provide safety redundance.

As before, the contactor driver output is used as a trigger to start counting time.

However, as there is no feedback contact, a new method is required for detecting when circuit closure occurs. There are two possible of methods for achieving this: (i) using voltage; or (ii) using current.

With the voltage method, when both terminals 110, 120 are engaged by the metal contact 130, the voltage on the load 420 will change. Detection of a change in voltage on the load 420 can be used as an indication that both terminals 110, 120 have been engaged by the metal contact 130 and the main circuit has been closed.

For example, where a passive circuit is used to balance the load side voltage around battery side negative, a voltage on the load side that is isolated from battery side will be centred around the battery negative terminal (for example, 500 V becomes+/−250 V relative to battery negative). Therefore, closing any of the contactors will move the voltage away from the centre, and this can be used to indicate that both contactor terminals 110, 120 have been engaged by the contactor.

In this case the time interval will be the time between the activation signal being sent to the contactor and a change in voltage being detected in the load circuit.

Alternatively, a biasing circuit can used that applies a small current from the battery pack side of the circuit to the load side of the circuit. Typically, the biasing circuit applies a current of the order of microamps. Closing the contactor closes the loop of this biasing circuit and creates a measurable voltage on load side, this is a possible trigger point.

In this case the time interval will be the time between the activation signal being sent to the contactor and a measurable voltage being detected in the load circuit.

With the current method, current sensors 430, 440 can be coupled to the load side of the circuit. When a current is detected on the load side, this can be used as an indicator that both positive and negative side contactors Cₙ and Cₚ or Cₚᵣ are closed.

In this case the time interval will be the time between the activation signal being sent to the contactor and an increase in current being detected in the load circuit.

When a system state machine is represented in software, it can determine which contactor of a plurality of contactor has been welded. A contactor may weld when it is in the process of closing and normally will not weld when it is already in a properly (fully) closed state. As the contactors close in sequence, only one contactor may be in this risky state at a time. Since a contactor only welds if there is some voltage that can cause an arc and some current that can cause enough heat, a contactor may only weld when the electrical circuit is about to be fully closed. This is why the first contactor to close will not weld. This is also why the last contactor to close is the one that can be welded. Knowing which contactor closed first and last also means knowing which contactor is safe and which contactor is unsafe. Therefore, as long as the information of which one was closed last is saved, the system can rule out which one is safe and which one is not safe until diagnostics has been run.

### Temperature Compensation

Temperature affects the resistance of the coil 210 which typically has a positive temperature coefficient, thereby affecting the current through the coil 210. Temperature will affect the resistance (positive temperature coefficient) of the coil 210, thereby the current through the coil 210. Thus lower temperatures will lead to a lower resistance of the coil 210, resulting in a higher current through the coil 210, and therefore a stronger solenoid and faster operation of the plunger 142. Likewise, higher temperatures will lead to slower operation of the plunger 142.

This will have an effect on the measured time even when the contactor is operating normally. The measured time can be corrected by applying a coefficient that is based on a measurement of the current temperature.

Another way is to compare the closing time measurement between two or more contactors, thereby removing the need to sense the temperature separately.

1. A method of indicating that a conducting member has not fully disengaged from two electrical contacts, the conducting member movably mounted on an actuator, the actuator being adapted to move between a deactivated position and an activated position, wherein in the activated position the conducting member is in contact with both the electrical contacts, the method comprising:
sending an activation signal to move the actuator to the activated position;
detecting that the actuator has caused an electrical circuit to be closed; and
if the time interval between the sending step and the detecting step is less than a threshold, generating an output indicating that the conducting member was not fully disengaged before the activation signal was sent.

2. The method of claim 1 wherein the generating comprises generating an output indicating that the conducting member was only partially disengaged before the activation signal was sent.

3. The method of claim 1 wherein the generating comprises generating an output indicating that the conducting member was fully engaged before the activation signal was sent.

4. The method of claim 1 wherein the electrical circuit that is closed comprises a feedback contact.

5. The method of claim 1, wherein the electrical circuit that is closed comprises the conducting member and the two electrical contacts.

6. The method of claim 1, wherein the threshold is based on a reference time interval between a sending of an activation signal to a reference actuator and detecting that the reference actuator has caused a reference circuit to be closed.

7. The method of claim 6 wherein the reference circuit comprises: a reference feedback contact, where the electrical circuit that is closed comprises a feedback contact; or a reference conducting member and two reference electrical contacts, where the electrical circuit that is closed comprises the conducting member and the two electrical contacts.

8. The method according to claim 1, wherein the conducting member, the two electrical contacts and the actuator are parts of an electrical contactor.

9. The method according to claim 1, wherein the contactor is located within a housing.

10. The method of claim 1 further comprising adjusting the time interval by applying a coefficient based on at least one physical characteristic.

11. The method of claim 10 wherein the at least one physical characteristic comprises one or more of temperature, current, wear, tolerances, and voltage.

12. The method of claim 10 wherein the at least one physical characteristic is one or more of a temperature of a coil comprised in the actuator or an ambient temperature of the surroundings of a coil comprised in the actuator, average electrical current through the conducting member, integral of electrical current through the conducting member, voltage across the actuator, and instant and weighted average voltage across the actuator.

13. The method of claim 10, wherein the conducting member, the two electrical contacts and the actuator are parts of an electrical contactor, and the at least one physical characteristic comprises a temperature of the contactor or an ambient temperature of surroundings of the contactor.

14. The method of claim 12 wherein the average is a weighted average.

15. The method according to claim 1, wherein the two electrical contacts comprise a part of a battery pack.

16. Apparatus for implementing the method according to claim 1, the apparatus comprising:
a processor; and
an output device;
wherein:
the processor causes the activation signal to be sent to the actuator to move the actuator to the activated position;
the processor detects that the actuator has caused an electrical circuit to be closed;
if the time interval between the sending step and the detecting step is less than a threshold, the processor generates an output that is sent to the output device to cause the output device to indicate that the conducting member was not fully disengaged before the activation signal was sent.

17. Apparatus according to claim 16, further comprising at least one sensor or detector to sense or detect at least one physical characteristic by adjusting the time interval by applying a coefficient based on the at least one physical characteristic.
